(19) United States
(12) Patent Application Publication
(10) Pub. No.: US 2025/0233590 A1
(43) Pub. Date: Jul. 17, 2025

(54) OUTPUT DRIVER AND OUTPUT BUFFER CIRCUIT INCLUDING THE SAME

(71) Applicant: SAMSUNG ELECTRONICS CO., LTD., SUWON-SI (KR)

(72) Inventors: EONGUK KIM, SUWON-SI (KR); JINSU JEONG, SUWON-SI (KR)

(21) Appl. No.: 19/010,480

(22) Filed: Jan. 6, 2025

(30) Foreign Application Priority Data
Jan. 12, 2024 (KR) 10-2024-0005375
Apr. 12, 2024 (KR) 10-2024-0049547

(51) Int. Cl. H03K 19/003

(52) U.S. Cl. CPC H03K 19/00315

(57) ABSTRACT

An output driver includes a driving circuit electrically connected to a pad and including at least two transistors connected to each other in series, and a leakage prevention circuit configured to block a leakage current of the driving circuit. Gates of the at least two transistors are electrically connected to each other, and the leakage prevention circuit is configured to control a voltage level of an intermediate node between the at least two transistors based on a signal level of the pad.

### CROSS-REFERENCE TO RELATED APPLICATIONS

This application claims priority under 35 U.S.C. § 119 to Korean Patent Application No. 10-2024-0005375 filed on Jan. 12, 2024, and Korean Patent Application No. 10-2024-0049547 filed on Apr. 12, 2024, the disclosures of which are incorporated by reference herein in their entireties.

### TECHNICAL FIELD

Embodiments of the present disclosure described herein relate to an output driver.

### DISCUSSION OF RELATED ART

Semiconductor chips typically include transistors with different gate oxide thicknesses based on their intended voltage application. Such transistors may include transistors with a thick gate oxide, primarily used at a high voltage (e.g., about 3.3 V), transistors with a thin gate oxide, primarily used at a low voltage (e.g., about 1.8 V), and transistors with a medium gate oxide, which are suitable for intermediate voltages.

For applications requiring a high-voltage interface, input/output circuits should be designed to operate under a high voltage. However, transistors with thin or medium gate oxides exhibit higher leakage currents compared to those with thick gate oxides. Therefore, input/output circuits designed for high-voltage operation typically use transistors with thick gate oxides to minimize leakage current.

### SUMMARY

Embodiments of the present disclosure provide an output driver that effectively blocks a leakage current while implementing the output driver using a transistor having a thin gate oxide or a medium gate oxide.

According to embodiments of the present application, an output driver is implemented using transistors including a thin gate oxide or a medium gate oxide. As a result, the output driver may effectively block a leakage current.

According to an embodiment of the present application, an output driver includes a driving circuit electrically connected to a pad and including at least two transistors connected to each other in series, and a leakage prevention circuit configured to block a leakage current of the driving circuit. Gates of the at least two transistors are electrically connected to each other, and the leakage prevention circuit is configured to control a voltage level of an intermediate node between the at least two transistors based on a signal level of the pad.

According to an embodiment of the present disclosure, a method of operating an output driver includes setting a state of the output driver in a high impedance state, inputting a signal at a high level or a low level to a pad connected to the output driver, and controlling a voltage level of an intermediate node between transistors of the output driver based on a level of the signal input to the pad.

According to an embodiment of the present disclosure, an output buffer circuit includes an output driver and a control logic circuit configured to control the output driver in response to a data signal and an enable signal. The output driver includes a driving circuit electrically connected to a pad and including at least two transistors connected to each other in series, and a leakage prevention circuit configured to block a leakage current of the driving circuit. Gates of the at least two transistors are electrically connected to each other, and the leakage prevention circuit is configured to control a voltage level of an intermediate node between the at least two transistors based on a signal level of the pad.

### BRIEF DESCRIPTION OF THE DRAWINGS

The above and other objects and features of the present disclosure will become more apparent by describing in detail embodiments thereof with reference to the accompanying drawings, in which:

FIG. 1 is a circuit diagram illustrating an output buffer circuit according to an embodiment of the present disclosure;

FIG. 2A is a circuit diagram illustrating an operation of a leakage prevention circuit of an output driver according to an embodiment of the present disclosure;

FIG. 2B is a circuit diagram illustrating an operation of a leakage prevention circuit of an output driver according to an embodiment of the present disclosure;

FIG. 3 is a circuit diagram illustrating an output buffer circuit according to an embodiment of the present disclosure;

FIG. 4A is a circuit diagram illustrating an operation of a leakage prevention circuit of an output driver according to an embodiment of the present disclosure;

FIG. 4B is a circuit diagram illustrating an operation of a leakage prevention circuit of an output driver according to an embodiment of the present disclosure;

FIG. 5 is a circuit diagram illustrating an output buffer circuit according to an embodiment of the present disclosure;

FIGS. 6 and 7 are circuit diagrams illustrating output buffer circuits according to embodiments of the present disclosure;

FIG. 8 is a block diagram illustrating an output driver according to an embodiment of the present disclosure;

FIG. 9A is a flowchart illustrating an operation of an output driver according to an embodiment of the present disclosure;

FIG. 9B is a flowchart illustrating an operation of an output driver according to an embodiment of the present disclosure; and

FIG. 10 is a block diagram illustrating devices to which an output driver or an output buffer circuit is applied and a system including the devices according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

As used herein, the term “and/or” includes any and all combinations of one or more of the associated listed items.

It will be understood that when an element is referred to as being “on”, “connected to”, “coupled to”, or “adjacent to” another element, it can be directly on, connected, coupled, or adjacent to the other element, or intervening elements may be present. It will also be understood that when an element is referred to as being “between” two elements, it can be the only element between the two elements, or one or more intervening elements may also be present. Other words used to describe the relationships between elements should be interpreted in a like fashion.

Embodiments of the present disclosure provide an output driver circuit designed to minimize or reduce leakage current in semiconductor devices. Embodiments provide a leakage prevention circuit that can effectively manage voltage levels at intermediate nodes between transistors within both pull-up and pull-down drivers. The configuration according to embodiments may enable the use of transistors with thin or medium gate oxides, which typically suffer from higher leakage currents compared to those with thick gate oxides. By controlling the intermediate node voltages based on the signal level at the output pad, the circuit can effectively reduce leakage in high-impedance states without the need for thick gate oxide transistors. This configuration may simplify the manufacturing process by avoiding the need for additional mask steps, and may reduce production costs, while maintaining efficient leakage control.

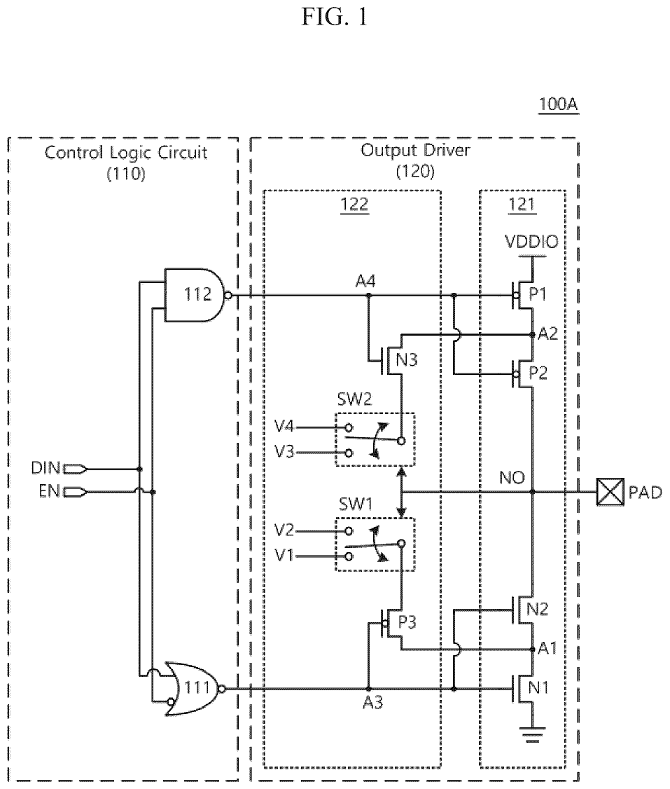

FIG. 1 is a circuit diagram illustrating an output buffer circuit 100A according to an embodiment of the present disclosure. For convenience of explanation, FIG. 1 shows a 3-state output buffer circuit as a representative example. However, embodiments of the present disclosure are not limited thereto.

The output buffer circuit 100A may include an output driver 120, and the output driver 120 may include at least two transistors connected to each other in series. Gates of the at least two transistors connected to each other in series may be electrically connected to each other. In addition, a voltage level of an intermediate node between the at least two transistors connected to each other in series may be controlled based on a signal level of a pad PAD. Accordingly, a leakage current of the output driver 120 may be effectively blocked. The output driver 120 may also be referred to as an output driver circuit.

Referring to FIG. 1, the output buffer circuit 100A may include a control logic circuit 110 and/or the output driver 120.

The control logic circuit 110 may include a NOR gate 111 and/or a NAND gate 112. A data signal DIN may be input to one input of the NOR gate 111, and an inverted signal of an enable signal EN may be input to the other input of the NOR gate 111. The data signal DIN may be input to one input of the NAND gate 112, and the enable signal EN may be input to the other input of the NAND gate 112.

When the enable signal EN has a low value, an output signal of the NAND gate 112 has a high value regardless of a value of the data signal DIN. In addition, an output signal of the NOR gate 111 has a low value regardless of the value of the data signal DIN. Therefore, all transistors P1, P2, N1, and N2 of a driving circuit 121 are turned off, and an output node NO is in a high impedance state.

When the enable signal EN has the high value and the data signal DIN has the low value, both the output signal of the NAND gate 112 and the output signal of the NOR gate 111 have the high value. Accordingly, n-type metal-oxide semiconductor (NMOS) transistors N1 and N2 of the driving circuit 121 are turned on, and the output node NO has the low value.

When the enable signal EN and the data signal DIN have the high value, both the output signal of the NAND gate 112 and the output signal of the NOR gate 111 have the low value. Accordingly, p-type metal-oxide semiconductor (PMOS) transistors P1 and P2 of the driving circuit 121 are turned on, and the output node NO has the high value.

As described above, the control logic circuit 110 may control the output driver 120 to allow the output buffer circuit 100A to operate in the 3-state output buffer circuit.

The output driver 120 may include the driving circuit 121 and a leakage prevention circuit 122. According to embodiments of the present disclosure, the leakage prevention circuit 122 may prevent or reduce a leakage current.

The driving circuit 121 may include a plurality of transistors.

As an example, the driving circuit 121 may include the NMOS transistors N1 and N2 connected to each other in series as shown in FIG. 1. One end of a first NMOS transistor N1 may be connected to a ground, and the other end of the first NMOS transistor N1 may be connected to a first node A1. One end of a second NMOS transistor N2 may be connected to the first node A1, and the other end of the second NMOS transistor N2 may be connected to the output node NO.

A gate of the first NMOS transistor N1 may be electrically connected to a gate of the second NMOS transistor N2. The first NMOS transistor N1 and the second NMOS transistor N2 may be referred to as a pull-down driver.

In addition, as an example, the driving circuit 121 may include the PMOS transistors P1 and P2 connected to each other in series. One end of a first PMOS transistor P1 may be connected to a power supply voltage terminal VDDIO, and the other end of the first PMOS transistor P1 may be connected to a second node A2. One end of a second PMOS transistor P2 may be connected to the second node A2, and the other end of the second PMOS transistor P2 may be connected to the output node NO.

A gate of the first PMOS transistor P1 may be electrically connected to a gate of the second PMOS transistor P2. The first PMOS transistor P1 and the second PMOS transistor P2 may be referred to as a pull-up driver.

According to an embodiment, the transistors N1, N2, P1, and P2 of the driving circuit 121 may be implemented by transistors including a thin gate oxide. That is, in embodiments, the pull-up driver or the pull-down driver does not include a transistor including a thick gate oxide or a transistor having a long channel. In other words, the pull-up driver or the pull-down driver may be implemented using only transistors including a thin gate oxide.

According to an embodiment, the transistors N1, N2, P1, and P2 of the driving circuit 121 may be implemented by transistors including a medium gate oxide. That is, in embodiments, the pull-up driver or the pull-down driver does not include a transistor including a thick gate oxide or a transistor having a long channel, and may be implemented using only transistors including a medium gate oxide. Thin gate oxide may refer to oxides with thicknesses in the nanometer range, and is often used, for example, for low-voltage transistors. Thick gate oxide may refer to oxides that are thicker than a typical gate oxide, and is often used, for example, in transistors designed to handle higher voltages, as thicker oxides can better withstand voltage stress. A medium gate oxide may refer to an oxide thickness that is intermediate between thin and thick gate oxides.

When the driving circuit 121 is implemented using transistors including a thick gate oxide or implemented using both transistors including a thin gate oxide and transistors including a thick gate oxide, a separate process is performed to implement the transistors including the thick gate oxide. In this case, since a mask process is further performed, a manufacturing cost of the output buffer circuit 100A increases, and difficulties in processes increases. In contrast, the driving circuit 121 according to embodiments of the present disclosure may be implemented using only transistors including a thin gate oxide or only transistors including a medium gate oxide, and thus, the increase in manufacturing cost and in process difficulties may be reduced.

Referring to FIG. 1, the leakage prevention circuit 122 may be implemented to block the leakage current of the driving circuit 121.

The leakage prevention circuit 122 may be implemented to control a voltage level of the first node A1 between the NMOS transistors N1 and N2 to block the leakage current of the NMOS transistors N1 and N2 that serve as the pull-down driver. To this end, the leakage prevention circuit 122 may include a third PMOS transistor P3 and a first switch SW1.

One end of the third PMOS transistor P3 may be connected to the first node A1 that is the intermediate node between the first and second NMOS transistors N1 and N2, and the other end of the third PMOS transistor P3 may be connected to the first switch SW1. In addition, a gate of the third PMOS transistor P3 may be connected to a third node A3.

The first switch SW1 may provide one of a first voltage V1 and a second voltage V2 to the one end of the third PMOS transistor P3 based on a voltage level of the output node NO. In other words, the first switch SW1 may provide one of the first voltage V1 and the second voltage V2 to the one end of the third PMOS transistor P3 based on the signal level of pad PAD.

In an embodiment, the second voltage V2 may have a voltage level higher than that of the first voltage V1. As an example, the first voltage V1 may be a ground voltage, and the second voltage V2 may be a power supply voltage VDD. According to an embodiment, as an example, the first voltage V1 may be the ground voltage VSS, and the second voltage V2 may have a voltage level higher than that of the ground voltage VSS and lower than that of the power supply voltage VDD. However, this is merely an example, and the voltage level of the first and second voltages V1 and V2 may be set in various ways according to embodiments of the present disclosure.

In addition, the leakage prevention circuit 122 may be implemented to control a voltage level of the second node A2 between the PMOS transistors P1 and P2 to block the leakage current of the PMOS transistors P1 and P2 that serve as the pull-up driver. To this end, the leakage prevention circuit 122 may include a third NMOS transistor N3 and a second switch SW2.

One end of the third NMOS transistor N3 may be connected to the second node A2 that is the intermediate node between the first and second PMOS transistors P1 and P2, and the other end of the third NMOS transistor N3 may be connected to the second switch SW2. In addition, a gate of the third NMOS transistor N3 may be connected to a fourth node A4.

The second switch SW2 may provide one of a third voltage V3 and a fourth voltage V4 to the one end of the third NMOS transistor N3 based on the voltage level of the output node NO. In other words, the second switch SW2 may provide one of the third voltage V3 and the fourth voltage V4 to the one end of the third NMOS transistor N3 based on the signal level of the pad PAD.

In an embodiment, the fourth voltage V4 may have a voltage level higher than that of the third voltage V3. As an example, the third voltage V3 may be the ground voltage VSS, and the fourth voltage V4 may be the power supply voltage VDD. According to an embodiment, as an example, the third voltage V3 may have a voltage level higher than that of the ground voltage VSS and lower than that of the power supply voltage VDD, and the fourth voltage V4 may be the power supply voltage VDD. However, this is merely an example, and the voltage level of the third and fourth voltages V3 and V4 may be set in various ways according to embodiments of the present disclosure.

As described above, the leakage prevention circuit 122 may control the voltage level of the first node A1 to block the leakage current in the pull-down driver or may control the voltage level of the second node A2 to block the leakage current in the pull-up driver.

In addition, the elements P3, N3, SW1, and SW2 constituting the leakage prevention circuit 122 may be implemented with a size smaller than that of the elements N1, N2, P1, and P2 constituting the driving circuit 121. That is, since the elements N3, P3, SW1, and SW2 constituting the leakage prevention circuit 122 act as switches, the elements N3, P3, SW1, and SW2 constituting the leakage prevention circuit 122 may be implemented with a size smaller than that of the elements N1, N2, P1, and P2 of the driving circuit 121 that serve as an output driver. Accordingly, an area occupied by the leakage prevention circuit 122 may be reduced, and thus, an overall size of the output driver 120 may decrease.

As described above, the output driver 120 may include the at least two transistors connected to each other in series. The gates of the at least two transistors connected to each other in series may be electrically connected to each other. In addition, the voltage level of the intermediate node between the at least two transistors connected to each other in series may be controlled based on the signal level of the pad PAD. Accordingly, the leakage current in the output driver 120 may be effectively blocked.

The control logic circuit 110 shown in FIG. 1 is merely an example, and embodiments of the present disclosure are not limited thereto. As an example, the control logic circuit 110 may be implemented using various logic circuits as long as the high impedance state may be set.

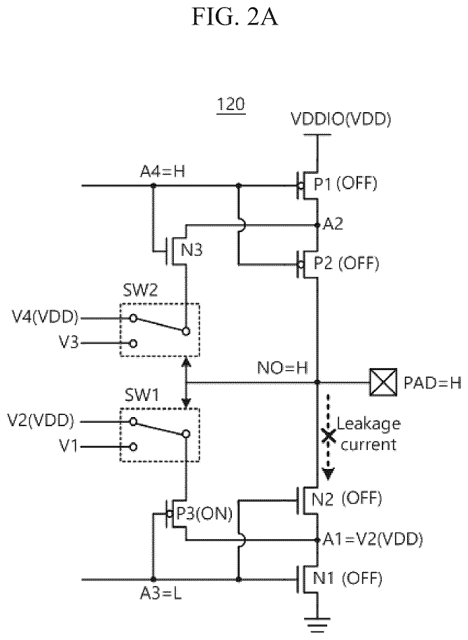

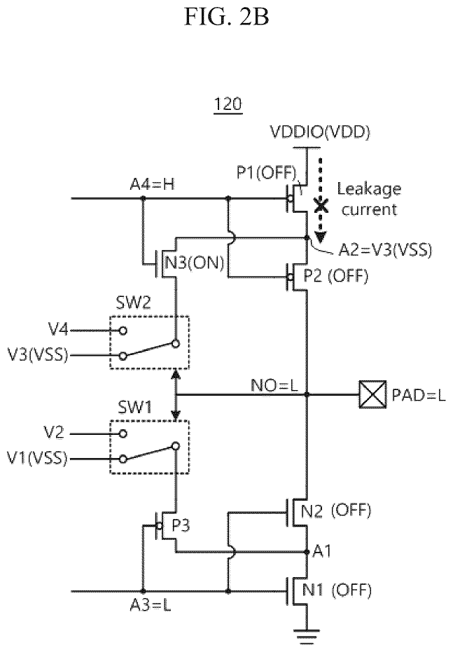

FIG. 2A is a circuit diagram illustrating an operation of the leakage prevention circuit 122 of the output driver 120 according to an embodiment of the present disclosure. The output driver 120 of FIG. 2A may correspond to the output driver 120 of FIG. 1.

FIG. 2A shows the operation of the leakage prevention circuit 122 of the output driver 120 when a signal at a high level (hereinafter, referred to as a “high signal”) is input to the pad PAD at the high impedance state as a representative example. For convenience of explanation, it is assumed that each of the second voltage V2 and the fourth voltage V4 has the voltage level of the power supply voltage VDD and the power supply voltage VDD is applied to the power supply voltage terminal VDDIO.

Referring to FIG. 2A, the third node A3 has the low value, and the fourth node A4 has the high value. Accordingly, the NMOS transistors N1 and N2 that are the pull-down driver and the PMOS transistors P1 and P2 that are the pull-up driver are turned off, and the output driver 120 may be in the high impedance state.

When the high signal is input to the pad PAD in the high impedance state, the leakage current may flow from the pad PAD to the ground via the turned-off first and second NMOS transistors N1 and N2.

In this case, the first switch SW1 may connect the second voltage V2 that is the power supply voltage VDD to the third PMOS transistor P3 based on the signal level of the pad PAD, which has a high level. In this case, since the third PMOS transistor P3 is in a turned-on state, the second voltage V2 that is the power supply voltage VDD may be transferred to the first node A1. Therefore, the voltage level of the first node A1 rises to the voltage level of the power supply voltage VDD.

Accordingly, a source potential of the second NMOS transistor N2 is higher than a gate potential of the second NMOS transistor N2, and thus, a gate-source potential Vgs of the second NMOS transistor N2 has a negative (−) value. Therefore, a channel leakage current of the second NMOS transistor N2 may be reduced, and consequently, the leakage current flowing from the pad PAD to the ground may be effectively blocked.

In addition, a leakage current path passing through the second PMOS transistor P2 and the third NMOS transistor N3 may be formed.

In this case, the second switch SW2 may connect the fourth voltage V4 that is the power supply voltage VDD to the third NMOS transistor N3 based on the signal level of the pad PAD, which has the high level. Accordingly, a source potential of the third NMOS transistor N3 may increase to the voltage level of the power supply voltage VDD, and thus, a leakage current passing through the second PMOS transistor P2 and the third NMOS transistor N3 may be effectively blocked.

Consequently, when the high signal is input to the pad PAD in the high impedance state, the leakage current of the output driver 120 may be effectively blocked.

FIG. 2B illustrates the operation of the leakage prevention circuit 122 of the output driver 120 as a representative example. The output driver 120 of FIG. 2B may correspond to the output driver 120 of FIG. 1.

FIG. 2B shows the operation of the leakage prevention circuit 122 of the output driver 120 when a signal at a low level (hereinafter, referred to as a “low signal”) is input to the pad PAD at the high impedance state as a representative example. For convenience of explanation, it is assumed that each of the first voltage V1 and the third voltage V3 has the voltage level of the ground voltage VSS and the power supply voltage VDD is applied to the power supply voltage terminal VDDIO.

Referring to FIG. 2B, the third node A3 has the low value, and the fourth node A4 has the high value. Accordingly, the output driver 120 is in the high impedance state.

When the low signal is input to the pad PAD at the high impedance state, the leakage current may flow from the power supply voltage terminal VDDIO to the pad PAD through the turned-off first and second PMOS transistors P1 and P2.

In this case, the second switch SW2 may connect the third voltage V3 that is the ground voltage VSS to the third NMOS transistor N3 based on the signal level of the pad PAD, which has the low level. In this case, since the third NMOS transistor N3 is in a turned-on state, the third voltage V3 having the voltage level of the ground voltage VSS is applied to the second node A2. Accordingly, the voltage level of the second node A2 drops to the voltage level of the ground voltage VSS.

Accordingly, a source potential of the second PMOS transistor P2 is lower than a gate potential of the second PMOS transistor P2, and thus, a gate-source potential of the second PMOS transistor P2 has a positive (+) value. Therefore, a channel leakage current of the second PMOS transistor P2 may be reduced, and consequently, the leakage current flowing from the power supply voltage terminal VDDIO to the pad PAD may be effectively blocked.

In addition, a leakage current path passing through the second NMOS transistor N2 and the third PMOS transistor P3 may be formed.

In this case, the first switch SW1 may connect the first voltage V1 that is the ground voltage VSS to the third PMOS transistor P3 based on the signal level of the pad PAD, which has the low level. Accordingly, a source potential of the third PMOS transistor P3 drops to the voltage level of the ground voltage VSS, and thus, the leakage current passing through the second NMOS transistor N2 and the third PMOS transistor P3 may also be effectively blocked.

Consequently, when the low signal is input to the pad PAD in the high impedance state, the leakage current of the output driver 120 may be effectively blocked.

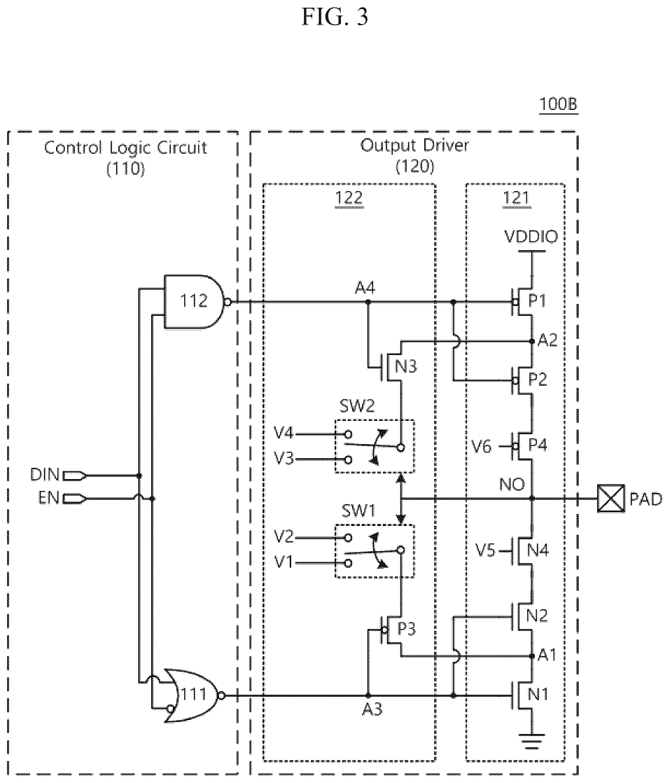

FIG. 3 is a circuit diagram illustrating an output buffer circuit 100B according to an embodiment of the present disclosure. The output buffer circuit 100B of FIG. 3 is similar to the output buffer circuit 100A of FIG. 1. Therefore, in FIG. 3, the same or similar elements as those in FIG. 1 are assigned with the same or similar reference numerals as those in FIG. 1, and thus, detailed descriptions of the same or similar elements will be omitted.

Referring to FIG. 3, the output buffer circuit 100B may include a control logic circuit 110 and an output driver 120, and the output driver 120 may include a driving circuit 121 and a leakage prevention circuit 122.

The driving circuit 121 may include a plurality of transistors. As an example, the driving circuit 121 may include NMOS transistors N1 and N2 connected to each other in series as shown in FIG. 3. A gate of a first NMOS transistor N1 may be electrically connected to a gate of a second NMOS transistor N2.

The driving circuit 121 may further include at least one NMOS transistor connected in series to the first and second NMOS transistors N1 and N2. As an example, as shown in FIG. 3, the driving circuit 121 may further include a fourth NMOS transistor N4, and the fourth NMOS transistor N4 may be disposed between the second NMOS transistor N2 and an output node NO.

A fifth voltage V5 may be applied to a gate of the fourth NMOS transistor N4. The fifth voltage V5 may have, for example, a voltage level higher than a ground voltage and lower than a power supply voltage VDD. However, this is merely an example, and the voltage level of the fifth voltage V5 may be set in various ways according to embodiments of the present disclosure.

The fourth NMOS transistor N4 may be used to control a value of a current flowing through a pull-down driver. As an example, when a high voltage is applied to a power supply voltage terminal VDDIO, the fourth NMOS transistor N4 may be used to control the value of the current flowing through the pull-down driver.

In addition, the driving circuit 121 may further include at least one PMOS transistor connected in series to first and second PMOS transistors P1 and P2. As an example, the driving circuit 121 may further include a fourth PMOS transistor P4, and the fourth PMOS transistor P4 may be disposed between the second PMOS transistor P2 and the output node NO as shown in FIG. 3.

A sixth voltage V6 may be applied to a gate of the fourth PMOS transistor P4. The sixth voltage V6 may have, for example, a voltage level higher than the ground voltage and lower than the power supply voltage VDD. However, this is merely an example, and the voltage level of the sixth voltage V6 may be set in various ways according to embodiments of the present disclosure.

The fourth PMOS transistor P4 may be used to control a value of a current flowing through a pull-up driver. As an example, when the high voltage is applied to the power supply voltage terminal VDDIO, the fourth PMOS transistor P4 may be used to control the value of the current flowing through the pull-up driver.

As described above, the output driver 120 may further include at least one NMOS transistor connected in series to the NMOS transistors of the pull-down driver. In addition, the output driver 120 may include at least one PMOS transistor connected in series to the PMOS transistors of the pull-up driver. Accordingly, even when the power supply voltage VDD is the high voltage, a leakage current in the output driver 120 may be effectively blocked.

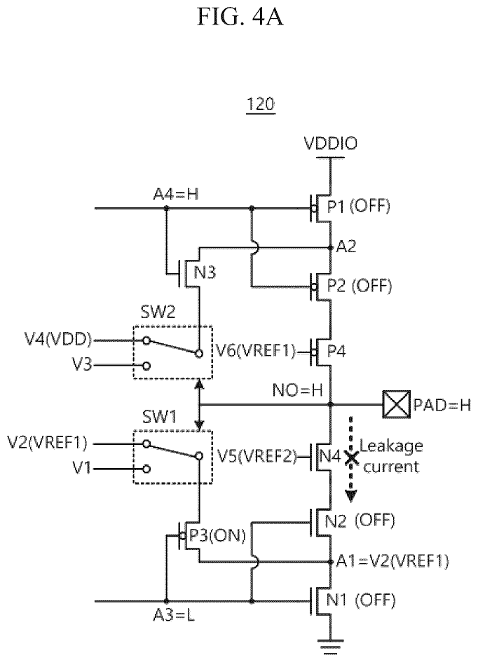

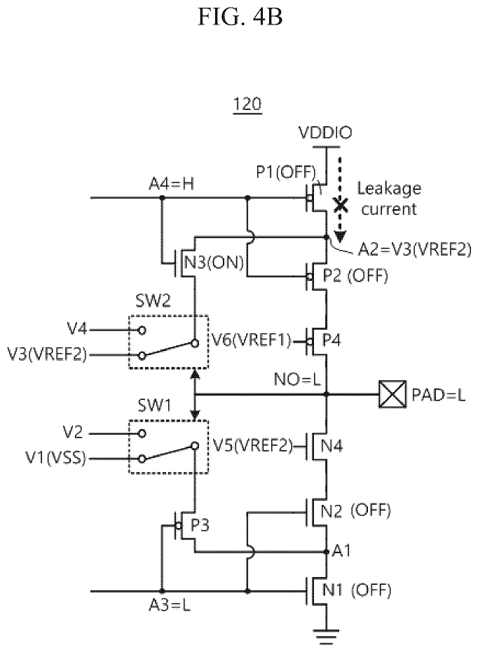

FIG. 4A is a circuit diagram illustrating an operation of the leakage prevention circuit 122 of the output driver 120 according to an embodiment of the present disclosure. The output driver 120 of FIG. 4A may correspond to the output driver 120 of FIG. 3.

FIG. 4A illustrates the operation of the leakage prevention circuit 122 of the output driver 120 when a high signal is input to a pad PAD in a high impedance state. For convenience of explanation, it is assumed that a second voltage V2 has a voltage level of a first reference voltage VREF1, a fourth voltage V4 has a voltage level of the power supply voltage VDD, the fifth voltage V5 has a voltage level of a second reference voltage VREF2, and the sixth voltage V6 has the voltage level of the first reference voltage VREF1.

Referring to FIG. 4A, a third node A3 has a low value, and a fourth node A4 has a high value. Accordingly, the output driver 120 is in the high impedance state.

When the high signal is input to the pad PAD in the high impedance state, the leakage current may flow from the pad PAD to a ground through the fourth NMOS transistor N4 and the first and second NMOS transistors N1 and N2.

In this case, a first switch SW1 may connect the second voltage V2 that is the first reference voltage VREF1 to a third PMOS transistor P3 based on the signal level of the pad PAD, which has a high level. Accordingly, a voltage level of a first node A1 rises to the first reference voltage VREF1. In this case, a gate-source potential (Vgs) of the second NMOS transistor N2 has a negative (−) value. Therefore, a channel leakage current of the second NMOS transistor N2 may be reduced, and consequently, the leakage current flowing from the pad PAD to the ground may be effectively blocked.

In an embodiment, the first and second reference voltages VREF1 and VREF2 may correspond to a voltage level higher than the ground voltage and lower than the power supply voltage VDD. As an example, the first reference voltage VREF1 may have a voltage level corresponding to about half of the power supply voltage VDD, and the second reference voltage VREF2 may also have a voltage level corresponding to about half of the power supply voltage VDD. According to embodiments, the first and second reference voltages VREF1 and VREF2 may be set to the same voltage level or set to different voltage levels.

In addition, a leakage current path may be formed through the fourth PMOS transistor P4, the second PMOS transistor P2, and a third NMOS transistor N3.

In this case, a second switch SW2 may connect the fourth voltage V4 that is the power supply voltage VDD to the third NMOS transistor N3 based on the signal level of the pad PAD, which has the high level. Accordingly, a source potential of the third NMOS transistor N3 may rise to the voltage level of the power supply voltage VDD, and thus, the leakage current passing through the fourth PMOS transistor P4, the second PMOS transistor P2, and the third NMOS transistor N3 may be effectively blocked.

Consequently, when the high signal is input to the pad PAD in the high impedance state, the leakage current of the output driver 120 may be effectively blocked.

FIG. 4B is a circuit diagram illustrating an operation of the leakage prevention circuit 122 of the output driver 120 according to an embodiment of the present disclosure. The output driver 120 of FIG. 4B may correspond to the output driver 120 of FIG. 3.

FIG. 4B illustrates the operation of the leakage prevention circuit 122 of the output driver 120 when a low signal is input to the pad PAD in the high impedance state. For convenience of explanation, it is assumed that a first voltage V1 has a voltage level of the ground voltage VSS, a third voltage V3 has the voltage level of the second reference voltage VREF2, the fifth voltage V5 has the voltage level of the second reference voltage VREF2, and the sixth voltage V6 has the voltage level of the first reference voltage VREF1.

Referring to FIG. 4B, the third node A3 has the low value, and the fourth node A4 has the high value. Accordingly, the output driver 120 may be in the high impedance state.

When the low signal is input to the pad PAD in the high impedance state, the leakage current may flow from the power supply voltage terminal VDDIO to the pad PAD through the first and second PMOS transistors P1 and P2 and the fourth PMOS transistor P4.

In this case, the second switch SW2 may connect the third voltage V3 that is the second reference voltage VREF2 to the third NMOS transistor N3 based on the signal level of the pad PAD, which has the low level. Accordingly, a voltage level of a second node A2 drops to the voltage level of the second reference voltage VREF2.

In this case, since a source potential of the second PMOS transistor P2 is lower than a gate potential of the second PMOS transistor P2, a gate-source potential (Vgs) of the second PMOS transistor P2 may have a positive (+) value. Therefore, a channel leakage current of the second PMOS transistor P2 may be reduced, and consequently, the leakage current flowing from the power supply voltage terminal VDDIO to the pad PAD may be effectively blocked.

In addition, a leakage current path may be formed through the fourth NMOS transistor N4, the second NMOS transistor N2, and the third PMOS transistor P3.

In this case, the first switch SW1 may connect the first voltage V1 that is the ground voltage VSS to the third PMOS transistor P3 based on the signal level of the pad PAD, which has the low level. Accordingly, a source potential of the third PMOS transistor P3 may drop to the voltage level of the ground voltage VSS, and thus, the leakage current passing through the fourth NMOS transistor N4, the second NMOS transistor N2, and the third PMOS transistor P3 may be effectively blocked.

Consequently, when the low signal is input to the pad PAD in the high impedance state, the leakage current of the output driver 120 may be effectively blocked.

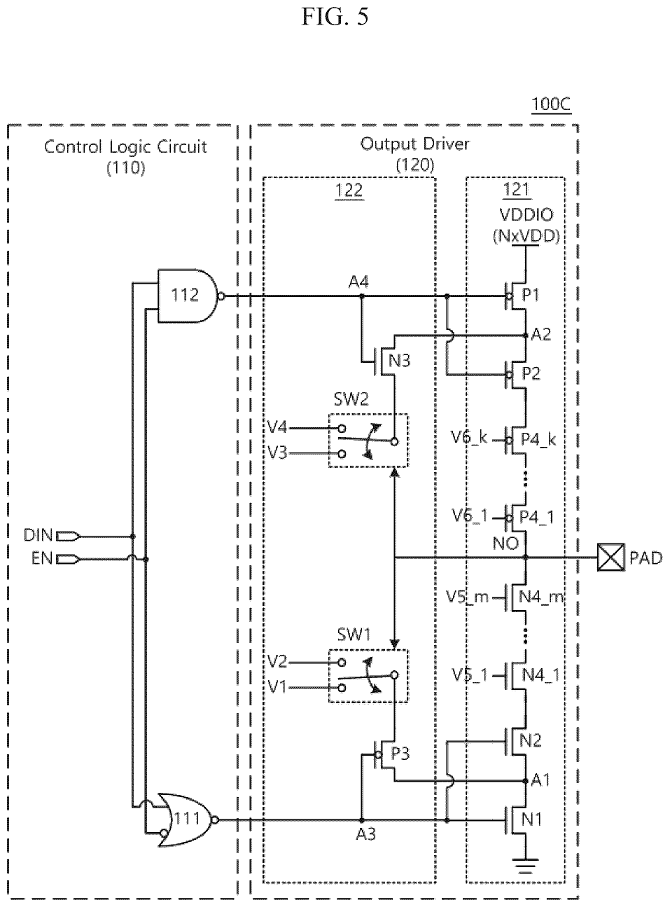

FIG. 5 is a circuit diagram illustrating an output buffer circuit 100C according to an embodiment of the present disclosure. The output buffer circuit 100C of FIG. 5 is similar to the output buffer circuits 100A and 100B of FIGS. 1 and 3. Therefore, in FIG. 5, the same or similar elements as those in FIGS. 1 and 3 are assigned with the same or similar reference numerals as those in FIGS. 1 and 3, and thus, detailed descriptions of the same or similar elements will be omitted.

Referring to FIG. 5, the output buffer circuit 100C may include a control logic circuit 110 and an output driver 120, and the output driver 120 may include a driving circuit 121 and a leakage prevention circuit 122.

A high voltage may be applied to a power supply voltage terminal VDDIO. As an example, a voltage that is N times (N is a positive integer equal to or greater than 2) of a power supply voltage VDD may be applied to the power supply voltage terminal VDDIO.

In this case, the driving circuit 121 may include a plurality of NMOS transistors to control a value of a current flowing through a pull-down driver. As an example, the NMOS transistors N4_1 to N4_m (m is a positive integer) connected to each other in series may be disposed between a second NMOS transistor N2 and an output node NO. Control voltages V5_1 to V5_m may be applied to gates of the NMOS transistors N4_1 to N4_m, respectively. A voltage level of the control voltages V5_1 to V5_m may be higher than a ground voltage and lower than the voltage level applied to the power supply voltage terminal VDDIO.

In addition, the driving circuit 121 may include a plurality of PMOS transistors to control a value of a current flowing through a pull-up driver. As an example, the PMOS transistors P4_1 to P4_k (k is a positive integer) may be disposed between a second PMOS transistor P2 and the output node NO. Control voltages V6_1 to V6_k may be applied to gates of the PMOS transistors P4_1 to P4_k, respectively. A voltage level of the control voltages V6_1 to V6_k may be higher than the ground voltage VSS and lower than the voltage level applied to the power supply voltage terminal VDDIO.

As described above, the high voltage corresponding to an integer multiple of the power supply voltage VDD may be applied to the power supply voltage terminal VDDIO of the output driver 120. In this case, the output driver 120 may further include a plurality of NMOS transistors connected in series to the NMOS transistors of the pull-down driver and a plurality of PMOS transistors connected in series to the PMOS transistors of the pull-up driver. Accordingly, even when the high voltage is applied to the power supply voltage terminal VDDIO, a leakage current in the output driver 120 may be effectively blocked.

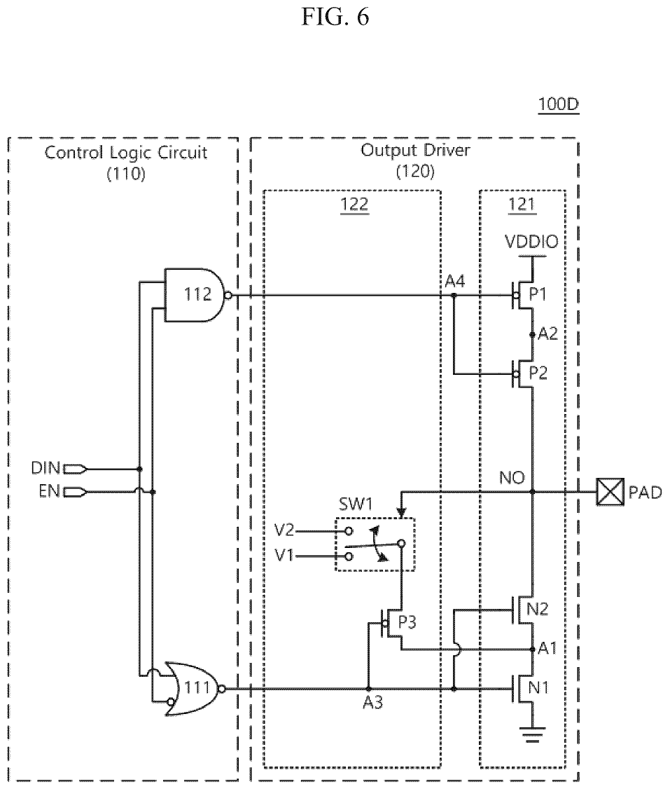

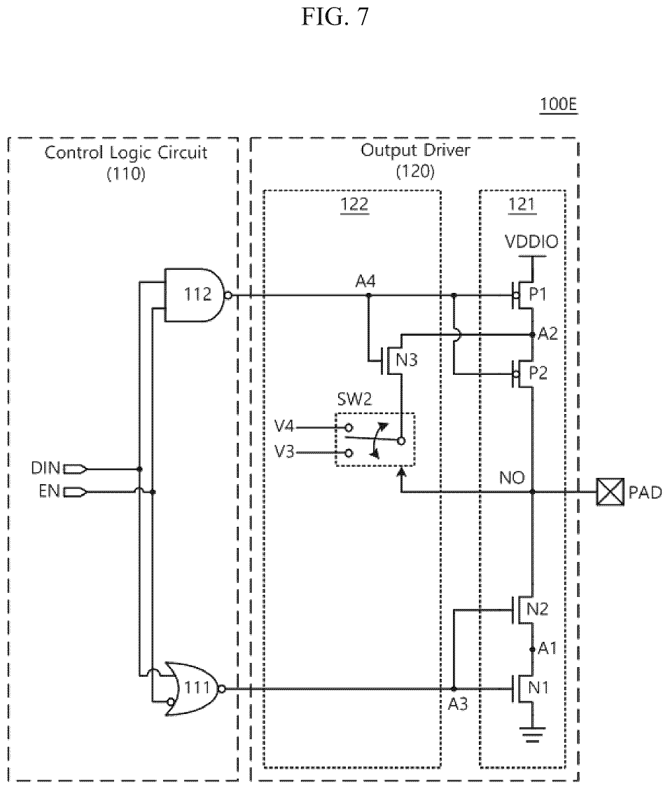

FIGS. 6 and 7 are circuit diagrams illustrating output buffer circuits 100D and 100E according to embodiments of the present disclosure. The output buffer circuits 100D and 100E of FIGS. 6 and 7 are similar to the output buffer circuits 100A, 100B, and 100C of FIGS. 1, 3, and 5. Therefore, in FIGS. 6 and 7, the same or similar elements as those in FIGS. 1, 3, and 5 are assigned with the same or similar reference numerals as those in FIGS. 1, 3, and 5, and thus, detailed descriptions of the same or similar elements will be omitted.

Referring to FIGS. 6 and 7, each of the output buffer circuits 100D and 100E may include a control logic circuit 110 and an output driver 120, and the output driver 120 may include a driving circuit 121 and a leakage prevention circuit 122. The leakage prevention circuit 122 may be implemented to block a leakage current of a pull-down driver or may be implemented to block a leakage current of a pull-up driver.

As shown in FIG. 6, the leakage prevention circuit 122 may be implemented to block a leakage current of first and second NMOS transistors N1 and N2 that serve as the pull-down driver. As an example, the leakage prevention circuit 122 may include a third PMOS transistor P3 and a first switch SW1 to control a voltage level of a first node A1 that is an intermediate node between the first NMOS transistor N1 and the second NMOS transistor N2.

As shown in FIG. 7, the leakage prevention circuit 122 may be implemented to block a leakage current of first and second PMOS transistors P1 and P2 that serve as the pull-up driver. As an example, the leakage prevention circuit 122 may include a third NMOS transistor N3 and a second switch SW2 to control a voltage level of a second node A2 that is an intermediate node between the first PMOS transistor P1 and the second PMOS transistor P2.

As described above, the output driver according to the present disclosure may be implemented to effectively block the leakage current in the pull-down driver or may be implemented to effectively block the leakage current in the pull-up driver.

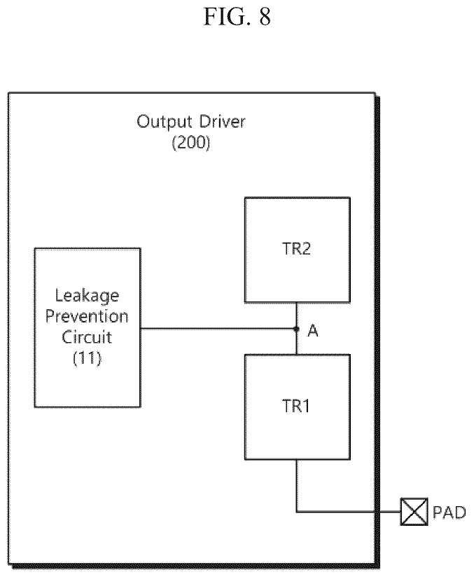

FIG. 8 is a block diagram illustrating an output driver according to an embodiment of the present disclosure. The output driver of FIG. 8 may correspond to one of the output drivers described with reference to FIGS. 1 to 7.

Referring to FIG. 8, the output driver 200 may include a first transistor TR1, a second transistor TR2, and a leakage prevention circuit 11. The output driver 200 may also be referred to as an output driver circuit.

The first transistor TR1 and the second transistor TR2 may be connected to each other in series, and a gate of the first transistor TR1 may be electrically connected to a gate of the second transistor TR2. One end of the first transistor TR1 and one end of the second transistor TR2 connected in series to the first transistor TR1 may be connected to a pad PAD.

As an example, the first transistor TR1 and the second transistor TR2 may serve as a pull-up driver. In this case, the other end of the first transistor TR1 and the other end of the second transistor TR2 connected in series to the first transistor TR1 may be connected to a power supply voltage terminal.

As an example, the first transistor TR1 and the second transistor TR2 may serve as a pull-down driver. In this case, the other end of the first transistor TR1 and the other end of the second transistor TR2 connected in series to the first transistor TR1 may be connected to a ground voltage.

The leakage prevention circuit 11 may be connected to an intermediate node A between the first and second transistors TR1 and TR2. The leakage prevention circuit 11 may control a voltage level of the intermediate node A between the first and second transistors TR1 and TR2 to block a leakage current flowing through the first and second transistors TR1 and TR2.

As an example, when each of the first and second transistors TR1 and TR2 is an NMOS transistor, the leakage prevention circuit 11 may control the voltage level of the intermediate node A to allow a gate-source potential (Vgs) of one of the first and second transistors TR1 and TR2 to have a negative (−) value. In this case, the one NMOS transistor may be turned off with greater certainty, and thus, the leakage current may be effectively blocked.

As another example, when each of the first and second transistors TR1 and TR2 is a PMOS transistor, the leakage prevention circuit 11 may control the voltage level of the intermediate node A to allow a gate-source potential (Vgs) of one of the first and second transistors TR1 and TR2 to have a positive (+) value. In this case, the one PMOS transistor may be turned off with greater certainly, and thus, the leakage current may be effectively blocked.

As described above, the output driver according to an embodiment controls the voltage level of the intermediate node between the transistors that operate as the pull-down or pull-up driver, and thus, the leakage current may be effectively blocked.

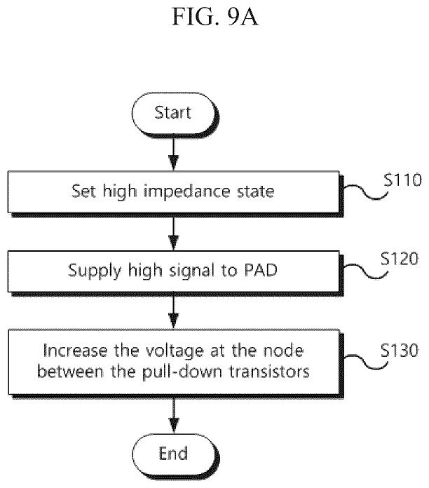

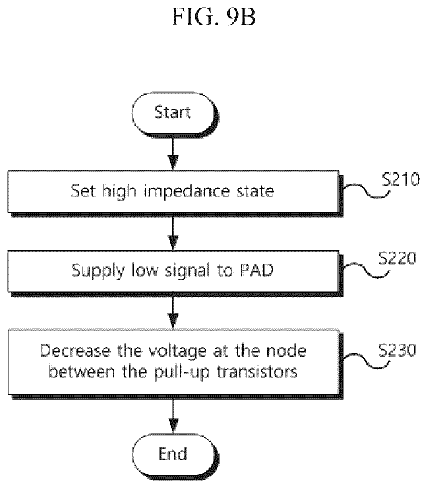

FIG. 9A is a flowchart illustrating an operation of the output driver according to an embodiment of the present disclosure. FIG. 9A shows the operation that blocks the leakage current when the high signal is input to the pad PAD.

In operation S110, the output driver may be set to the high impedance state.

As an example, both the NMOS transistors that serve as the pull-down driver and the PMOS transistors that serve as the pull-up driver may be turned off as described with reference to FIGS. 2A and 2B.

In operation S120, the high signal may be input to the pad.

As an example, the high signal may be input to the pad PAD as shown in FIG. 2A. Therefore, the leakage current flowing from the pad PAD to the ground voltage may be generated in the high impedance state.

In operation S130, the voltage level of the node between the pull-down transistors may increase.

As an example, as shown in FIG. 2A, the first and second NMOS transistors N1 and N2 that serve as the pull-down driver may be connected to each other in series, and the gates of the first and second NMOS transistors N1 and N2 may be electrically connected to each other. In this case, the voltage level of the first node A1 that is the intermediate node between the first and second NMOS transistors N1 and N2 may increase. Accordingly, the second NMOS transistor N2 may be turned off with greater certainty, and consequently, the leakage current flowing through the first and second NMOS transistors N1 and N2 may be effectively blocked.

FIG. 9B is a flowchart illustrating an operation of the output driver according to an embodiment of the present disclosure. FIG. 9B shows the operation that blocks the leakage current when the low signal is input to the pad PAD.

In operation 210, the output driver may be set to the high impedance state.

In operation S220, the low signal may be input to the pad.

As an example, the low signal may be input to the pad PAD as shown in FIG. 2B. Therefore, the leakage current flowing from the power supply voltage terminal VDDIO to the pad PAD may be generated in the high impedance state.

In operation S230, the voltage level of the node between the pull-up transistors may increase.

As an example, as shown in FIG. 2B, the first and second PMOS transistors P1 and P2 that serve as the pull-up driver may be connected to each other in series, and the gates of the first and second PMOS transistors P1 and P2 may be electrically connected to each other. In this case, the voltage level of the second node A2 that is the intermediate node between the first and second PMOS transistors P1 and P2 may decrease. Accordingly, the second PMOS transistor P2 may be turned off with greater certainty, and consequently, the leakage current flowing through the first and second PMOS transistors P1 and P2 may be effectively blocked.

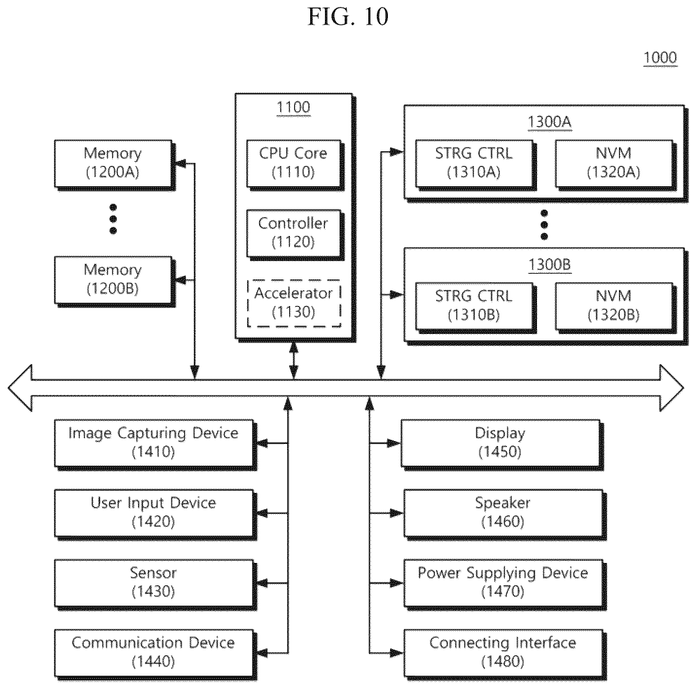

FIG. 10 is a block diagram illustrating devices to which the output driver or the output buffer circuit is applied, and a system 1000 including the devices according to an embodiment of the present disclosure.

The system 1000 of FIG. 10 may be, for example, a mobile system, such as a portable communication terminal, a smartphone, a tablet personal computer (PC), a wearable device, or a healthcare device. According to an embodiment, the system 1000 of FIG. 10 may be, for example, a PC, a laptop computer, a server, a media player, or an automotive device (e.g., a navigation device).

Referring to FIG. 10, the system 1000 may include a main processor 1100, memories 1200A and 1200B, and storage devices 1300A and 1300B. In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000. The main processor 1100 may be implemented as, for example, a general-purpose processor, a dedicated processor, or an application processor.

The main processor 1100 may include at least one CPU core 1110. In addition, the main processor 1100 may further include a controller 1120 configured to control the memories 1200A and 1200B and/or the storage devices 1300A and 1300B. In some embodiments, the main processor 1100 may further include an accelerator 1130, which is a dedicated circuit for a high-speed data operation, such as an artificial intelligence (AI) data operation. The accelerator 1130 may include, for example, a graphics processing unit (GPU), a neural processing unit (NPU) and/or a data processing unit (DPU), and may be implemented as a chip that is physically separate from the other components of the main processor 1100. The memories 1200A and 1200B may be used as main memory devices of the system 1000 and may include, for example, a volatile memory, such as static random access memory (SRAM) and/or dynamic RAM (DRAM). However, this is merely an example, and according to embodiments, the memories 1200A and 1200B may include a non-volatile memory, such as a flash memory, phase-change RAM (PRAM) and/or resistive RAM (RRAM).

The storage devices 1300A and 1300B may serve as non-volatile storage devices configured to store data regardless of whether power is supplied thereto. The storage devices 1300A and 1300B may respectively include storage controllers 1310A and 1310B and non-volatile memories 1320A and 1320B configured to store data under the control of the storage controllers 1310A and 1310B.

The image capturing device 1410 may capture still images or videos. The image capturing device 1410 may include, for example, a camera, a camcorder, and/or a webcam.

The user input device 1420 may receive various types of data input by a user of the system 1000 and include, for example, a touch pad, a keypad, a keyboard, a mouse, and/or a microphone.

The sensor 1430 may detect various types of physical quantities, which may be obtained from the outside of the system 1000, and may convert the detected physical quantities into electric signals. The sensor 1430 may include, for example, a temperature sensor, a pressure sensor, an illuminance sensor, a position sensor, an acceleration sensor, a biosensor, and/or a gyroscope sensor.

The communication device 1440 may transmit and receive signals between the system 1000 and other devices outside the system 1000 according to various communication protocols. The communication device 1440 may include, for example, an antenna, a transceiver, or a modem.

The display 1450 and the speaker 1460 may serve as output devices configured to respectively output visual information and auditory information to the user of the system 1000.

The power supplying device 1470 may appropriately convert power supplied from a battery embedded in the system 1000 and/or an external power source, and may supply the converted power to each of components of the system 1000.

The connecting interface 1480 may provide connection between the system 1000 and an external device. The connecting interface 1480 may be implemented by using various interface schemes, such as, for example, advanced technology attachment (ATA), serial ATA (SATA), external SATA (e-SATA), small computer small interface (SCSI), serial attached SCSI (SAS), peripheral component interconnection (PCI), PCI express (PCIe), NMVe, and a universal serial bus (USB) interface.

According to an embodiment, at least one of components of the system 1000 may include the output driver and/or the output buffer circuit described with reference to FIGS. 1 to 9. Accordingly, the leakage current in each component of the system 1000 may be effectively blocked.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An output driver, comprising:
a driving circuit electrically connected to a pad and comprising at least two transistors connected to each other in series; and
a leakage prevention circuit configured to block a leakage current of the driving circuit,
wherein gates of the at least two transistors are electrically connected to each other, and the leakage prevention circuit is configured to control a voltage level of an intermediate node between the at least two transistors based on a signal level of the pad.

2. The output driver of claim 1,
wherein the at least two transistors comprise:
a first n-type metal-oxide semiconductor (NMOS) transistor disposed between a ground voltage and a first node; and
a second NMOS transistor disposed between the first node and the pad,
wherein the leakage prevention circuit comprises:
a p-type metal-oxide semiconductor (PMOS) transistor connected to the first node; and
a switch connected to the PMOS transistor and configured to apply one of a first voltage and a second voltage to the PMOS transistor based on the signal level of the pad.

3. The output driver of claim 2, wherein a gate of the first NMOS transistor, a gate of the second NMOS transistor, and a gate of the PMOS transistor are commonly connected to a second node.

4. The output driver of claim 3, wherein the second voltage has a voltage level higher than a voltage level of the first voltage, and when a signal at a low level is input to the second node and a signal at a high level is input to the pad, the switch applies the second voltage to the first node through the PMOS transistor based on the signal level of the pad, which corresponds to the high level.

5. The output driver of claim 3, further comprising:
at least one NMOS transistor disposed between the second NMOS transistor and the pad,
wherein a reference voltage higher than the ground voltage is applied to a gate of the at least one NMOS transistor.

6. The output driver of claim 2, wherein the PMOS transistor has a size smaller than a size of the first and second NMOS transistors.

7. The output driver of claim 1,
wherein the at least two transistors comprise:
a first p-type metal-oxide semiconductor (PMOS) transistor disposed between a power supply voltage terminal and a first node; and
a second PMOS transistor disposed between the first node and the pad,
wherein the leakage prevention circuit comprises:
an n-type metal-oxide semiconductor (NMOS) transistor connected to the first node; and
a switch connected to the NMOS transistor and configured to apply one of a first voltage and a second voltage to the NMOS transistor based on the signal level of the pad.

8. The output driver of claim 7, wherein a gate of the first PMOS transistor, a gate of the second PMOS transistor, and a gate of the NMOS transistor are commonly connected to a second node.

9. The output driver of claim 8, wherein the second voltage has a voltage level higher than a voltage level of the first voltage, and when a signal at a high level is input to the second node and a signal at a low level is input to the pad, the switch applies the first voltage to the first node through the NMOS transistor based on the signal level of the pad, which corresponds to the low level.

10. The output driver of claim 8, further comprising:
at least one PMOS transistor disposed between the second PMOS transistor and the pad,
wherein a reference voltage higher than a ground voltage is applied to a gate of the at least one PMOS transistor.

11. The output driver of claim 7, wherein the NMOS transistor has a size smaller than a size of the first and second PMOS transistors.

12. The output driver of claim 1, wherein the at least two transistors of the driving circuit comprise a thin gate oxide layer.

13. A method of operating an output driver, comprising:
setting a state of the output driver in a high impedance state;
inputting a signal at a high level or a low level to a pad connected to the output driver; and
controlling a voltage level of an intermediate node between transistors of the output driver based on a level of the signal input to the pad.

14. The method of claim 13, wherein a voltage of the intermediate node between the transistors of the output driver increases when the signal at the high level is input to the pad.

15. The method of claim 13, wherein a voltage of the intermediate node between the transistors of the output driver decreases when the signal at the low level is input to the pad.

16. An output buffer circuit, comprising:
an output driver; and
a control logic circuit configured to control the output driver in response to a data signal and an enable signal, the output driver comprising:
a driving circuit electrically connected to a pad and comprising at least two transistors connected to each other in series; and
a leakage prevention circuit configured to block a leakage current of the driving circuit,
wherein gates of the at least two transistors are electrically connected to each other, and the leakage prevention circuit is configured to control a voltage level of an intermediate node between the at least two transistors based on a signal level of the pad.

17. The output buffer circuit of claim 16,
wherein the at least two transistors comprise:
a first n-type metal-oxide semiconductor (NMOS) transistor disposed between a ground voltage and a first node;
a second NMOS transistor disposed between the first node and the pad;
a first p-type metal-oxide semiconductor (PMOS) transistor disposed between a power supply voltage terminal and a second node; and
a second PMOS transistor disposed between the second node and the pad,
wherein the leakage prevention circuit comprises:
a third PMOS transistor connected to the first node;
a first switch connected to the third PMOS transistor and configured to apply one of a first voltage and a second voltage to the third PMOS transistor based on the signal level of the pad;
a third NMOS transistor connected to the second node; and
a second switch connected to the third NMOS transistor and configured to apply one of a third voltage and a fourth voltage to the third NMOS transistor based on the signal level of the pad.

18. The output buffer circuit of claim 17, wherein a gate of the first NMOS transistor, a gate of the second NMOS transistor, and a gate of the third PMOS transistor are commonly connected to a third node.

19. The output buffer circuit of claim 17, wherein a gate of the first PMOS transistor, a gate of the second PMOS transistor, and a gate of the third NMOS transistor are commonly connected to a third node.

20. The output buffer circuit of claim 17, further comprising:
at least one NMOS transistor disposed between the second NMOS transistor and the pad; and
at least one PMOS transistor disposed between the second PMOS transistor and the pad.
